(19) United States
(12) Patent Application Publication
(10) Pub. No.: US 2010/0236606 A1
(43) Pub. Date: Sep. 23, 2010

(54) PHOTOELECTRIC CONVERSION DEVICE AND SOLAR CELL, AND PROCESS FOR PRODUCING THE PHOTOELECTRIC CONVERSION DEVICE

(75) Inventors: Hiroyuki Kobayashi, Kanagawa-ken (JP); Shinya Suzuki, Kanagawa-ken (JP); Toshiaki Fukunaga, Kanagawa-ken (JP); Atsushi Mukai, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/721,314

(22) Filed: Mar. 10, 2010

(30) Foreign Application Priority Data
Mar. 10, 2009 (JP) 056164/2009

(51) Int. Cl. H01L 27/142; H01L 31/0216; H01L 31/18

(52) U.S. Cl. 136/249; 136/256; 438/93; 257/E27.123; 257/E27.124; 257/E31.119

(57) ABSTRACT

A photoelectric conversion device wherein a lower electrode, a photoelectric-conversion semiconductor layer of a compound semiconductor material, and an upper electrode are formed in this order on an anodized substrate in which an anodized oxide film as an insulating film is formed on an aluminum base arranged at at least one surface of a metal substrate. The lower electrode is formed on the anodized oxide film. The main component of the photoelectric-conversion semiconductor layer is a compound semiconductor material with a chalcopyrite structure of Group Ib, IIIb and VIb elements. The photoelectric conversion device includes at least one insulative alkali supply layer formed between the anodized substrate and the lower electrode, and at least one insulative antidiffusion layer being formed between the anodized substrate and the at least one alkali supply layer, and suppressing diffusion, toward the anodized substrate, of one or more alkali and/or alkaline earth metal elements.

### BACKGROUND OF THE INVENTION

1. Field of the Invention

The present invention relates to a photoelectric conversion device having on an anodized substrate a laminated structure constituted by a lower electrode, a photoelectric-conversion semiconductor layer, and an upper electrode. The present invention also relates to a solar cell using such a photoelectric conversion device.

2. Description of the Related Art

Currently, photoelectric conversion devices having a laminated structure constituted by a lower (underside) electrode, a photoelectric-conversion semiconductor layer, and an upper electrode are used in various applications including the solar cell. The photoelectric-conversion semiconductor layer generates electric current when the photoelectric-conversion semiconductor layer absorbs light.

Conventionally, the Si-based solar cell using bulk monocrystalline Si, bulk polycrystalline Si, or thin-film amorphous Si have been the mainstream of the solar cells. However, research and development of semiconductor compound-based solar cells not depending on silicon are proceeding. The currently known semiconductor compound-based solar cells include the bulk type solar cells such as the GaAs-based solar cells and the thin-film type solar cells such as the CIS (Cu—In—Se)-based or CIGS (Cu—In—Ga—Se)-based solar cells. The CIS-based or CIGS-based solar cells use semiconductor compounds composed of one or more Group Ib elements, one or more Group IIIb elements, and one or more Group VIb elements, and are reported to exhibit high optical absorptance and high energy conversion efficiency.

Although, currently, the glass substrate is mainly used as the substrate in the solar cell, use of a flexible metal substrate is being considered in response to demands for flexible devices. In the case where a metal substrate is used, it is necessary to form an insulation layer on a surface of the substrate for preventing short circuiting between the substrate and an electrode or a photoelectric conversion layer formed over the substrate.

In the case where an insulation layer is formed on the metal substrate by the conventional vapor phase deposition or liquid phase deposition, the adhesion strength is likely to decrease in some regions of the interface between the metal substrate and the insulation layer, and peeling of the insulation layer off the metal substrate, which is caused by external force, is likely to originate from the regions in which the adhesion strength is decreased. Further, it is conventionally considered preferable to form the photoelectric conversion layer by baking at 200° C. to 300° C. in the case of amorphous Si and at 500° C. in the case of CIS-based material. However, thermal stress occurs in the photoelectric conversion layer during the manufacturing process. Therefore, peeling of the insulation film is likely to occur, so that the reliability of the photoelectric conversion device decreases.

In addition, since the liquid phase deposition such as the sol-gel technique cannot produce a satisfactory film, it is difficult to obtain an insulation film which exhibits sufficiently high withstand voltage. Further, the cost of producing, by vapor phase deposition such as sputtering, a film with a thickness realizing a sufficient withstand voltage is unnecessarily high.

On the other hand, the anodized aluminum film (i.e., the film oxidized by anodization of an aluminum base) is superior in the adhesiveness between the base and the oxide film since the anodized film is continuously grown from the base.

Japanese Unexamined Patent Publication No. 2000-349320 (which is hereinafter referred to as JP2000-349320A) proposes use, as a substrate for a solar cell, of an anodized substrate produced by forming a porous anodized (Al₂O₃) film on an Al base. According to the technique disclosed in JP2000-349320A, even in the case where the area of the substrate is large, it is possible to form an insulation film over the entire surface of the substrate with high adhesiveness and no pinhole. In addition, some contrivance in the anodization enables formation of micropores and maintaining of surface flatness. Further, an anchor effect produced by the micropores can improve the adhesiveness between the anodized film and a film formed on the anodized film. It is known that an anodized film having a thickness of several to hundreds of micrometers can be easily produced by anodization.

On the other hand, it is known that the crystallinity and the photoelectric conversion efficiency of the photoelectric conversion layers in the photoelectric conversion devices such as the CIS-based and CIGS-based photoelectric conversion devices can be improved by diffusing an alkali (or an alkaline earth) metal element (preferably sodium) into the photoelectric conversion layers. Conventionally, sodium is supplied to the photoelectric conversion layers by using a substrate of soda lime glass (which contains sodium).

For the case where a metal substrate or the like other than the substrate of soda lime glass is used, Japanese Unexamined Patent Publications Nos. 10 (1998)-074966, 10 (1998)-074967, 9 (1997)-055378, 10 (1998)-125941, 2005-117012, 2006-210424, 2003-318424, 2005-086167, 8 (1995)-222750, 2004-158556, and 2004-079858 propose formation of a layer of a sodium compound such as Na₂Se, Na₂O, Na₂S, sodium phosphate, Na₃AlF₆, NaF between a Mo electrode and the substrate and/or a light absorption layer by evaporation, sputtering, coating, or the like in order to supply Na to a photoelectric conversion layer during formation of the photoelectric conversion layer. Further, for the case where a metal substrate is used in a solar cell using a chalcopyrite semiconductor, pct Japanese Publication No. 10 (1998)-512096 proposes forming a glass layer on the metal substrate so that the glass layer behaves as an insulation layer between the substrate and a photoelectric conversion layer, increases the withstand voltage of the substrate, and decreases the cost of the substrate.

In the case where the anodized substrate disclosed in JP2000-349320A is used, the substrate does not contain the alkali (or alkaline earth) metal element. Therefore, in order to achieve satisfactory photoelectric conversion efficiency, the alkali (or alkaline earth) metal element is required to be supplied to the photoelectric conversion layer in a manner other than the diffusion from the substrate. However, the devices in which a Na-containing layer is formed on an underside electrode by evaporation, sputtering, coating, or the like as disclosed in Japanese Unexamined Patent Publications Nos. 10 (1998)-074966, 10 (1998)-074967, 9 (1997)-055378, 10 (1998)-125941, 2005-117012, 2006-210424, 2003-318424, 2005-086167, 9 (1997)-222750, 2004-158556, and 2004-079858 are known to be uneasy to handle, poor in reproducibility, and likely to cause deterioration and peeling of the Na-containing layer, because of deliquescence and the like.

Further, in the case where the glass layer is used as the insulation layer as disclosed in Japanese Unexamined Patent Publication No. 10 (1998)-512096, peeling can occur depending on the type of the metal substrate because of the difference in the thermal expansion coefficient between the metal substrate and the photoelectric conversion layer. Further, in the case where the device is made flexible, it is difficult to thicken insulation layer so as to realize sufficient withstand voltage.

Furthermore, Japanese Unexamined Patent Publication No. 2009-267332 (which is hereinafter referred to as JP2009-267332A) discloses a substrate for a solar cell in which a first insulative oxide film is formed on a metal substrate of Al or the like by anodization, and a second insulative oxide film is formed on the first insulative oxide film by using a water solution of sodium silicate or the like in the hydrophilic treatment of the anodized film so that the second insulative oxide film contains alkali metal ions.

However, in the substrate for the solar cell disclosed in JP2009-267332A, the alkali metal ions can diffuse toward the metal substrate during the film formation, and supply of the alkali metal ions to the photoelectric conversion layer can become insufficient. In addition, since the diffusion of the alkali metal ions to the substrate causes deterioration of the anodized film, the distortion of the device after the formation of the photoelectric conversion layer can increase, and microcracks, film peeling, and the like can occur in the photoelectric conversion layer, so that the withstand voltage can decrease.

### SUMMARY OF THE INVENTION

The present invention has been developed in view of the above circumstances.

An object of the present invention is to provide a photoelectric conversion device which uses a metal substrate and exhibits superior photoelectric conversion efficiency, and in which a photoelectric conversion layer is satisfactorily doped with alkali metal with high reproducibility.

Another object of the present invention is to provide a photoelectric conversion device which has reduced distortion, and in which occurrence of cracks, film peeling, and the like is suppressed.

In a photoelectric conversion device according to the present invention, a lower electrode, a photoelectric-conversion semiconductor layer of a compound semiconductor material, and an upper electrode are formed in this order on an anodized substrate in which an anodized oxide film as an electrically insulating film is formed on an aluminum base arranged at at least one surface of a metal substrate, and the lower electrode is formed on the anodized oxide film. The photoelectric conversion device is characterized in that the photoelectric-conversion semiconductor layer contains as a main component at least one compound semiconductor material having a chalcopyrite structure and being composed of at least one Group Ib element, at least one Group IIIb element, and at least one Group VIb element; and the photoelectric conversion device includes: at least one alkali supply layer which is insulative and formed between the anodized substrate and the lower electrode, contains at least one of alkali and/or alkaline earth metal elements, and supplies the at least one of alkali and/or alkaline earth metal elements to the photoelectric-conversion semiconductor layer during formation of the photoelectric-conversion semiconductor layer; and at least one antidiffusion layer which is insulative and formed between the anodized substrate and the at least one alkali supply layer, and suppresses diffusion, toward the anodized substrate, of the at least one of alkali and/or alkaline earth metal elements contained in the at least one alkali supply layer.

In this specification, the expression “main component” means at least one component the content of which is 90 weight percent or higher, the numbering of the groups of elements are in accordance with the short-period form of the periodic table, and the semiconductor compound composed of at least one Group Ib element, at least one Group IIIb element, and at least one Group VIb element may be referred to as the Group I-III-VI semiconductor.

It is preferable that in the main component of the photoelectric-conversion semiconductor layer, the at least one Group Ib element be at least one of copper and silver, the at least one Group IIIb element be at least one of aluminum, gallium, and indium, and the at least one Group VIb element be at least one of sulfur, selenium, and tellurium.

The lower electrode preferably contains molybdenum as a main component.

The at least one antidiffusion layer is preferably formed of one or more oxides having a thermal expansion coefficient which is approximately identical to the thermal expansion coefficient of aluminum oxide at 300K. (The at least one antidiffusion layer may contain inevitable impurities.)

In this specification, unless otherwise specified, the linear thermal expansion coefficient of a material (having a composition) is defined as the linear thermal expansion coefficient, at 300K, of a bulk body having the same composition. The linear expansion coefficient of aluminum oxide is 5.4×10⁻⁶/K. In this specification, the materials having the linear expansion coefficient of 5.4×10⁻⁶/K±2.5×10⁻⁶/K (i.e., in the range from 2.9×10⁻⁶/K to 7.9×10⁻⁶/K) are defined as the materials having the linear expansion coefficient approximately identical to the linear expansion coefficient of aluminum oxide.

The at least one antidiffusion layer preferably contains SiO₂ and/or TiO₂ as one or more main components.

The an average thickness of the at least one antidiffusion layer is preferably 10 to 200 nanometers, and are preferably 10 to 100 nanometers.

Preferably, the at least one alkali supply layer contains sodium, and more preferably, the at least one alkali supply layer is formed of silicate glass containing a sodium compound.

The at least one alkali supply layer is preferably formed by sputtering.

The at least one alkali supply layer preferably has an average thickness of 50 to 200 nanometers.

The metal substrate may be an aluminum substrate. (The aluminum substrate may contain inevitable impurities.) However, it is preferable that in the metal substrate, the aluminum base be arranged on at least one surface of a metal base and be integrally formed with the metal base, and the metal base has a linear thermal expansion coefficient smaller than the linear thermal expansion coefficient of aluminum.

The anodized oxide film preferably has a porous structure.

In a preferable aspect of the photoelectric conversion device according to the present invention, the metal substrate is a laminated substrate in which the aluminum base is arranged on at least one surface of a base and is integrally formed with the base, where the base is made of a carbon steel or a ferritic stainless steel. (The base may contain inevitable impurities.) In addition, the lower electrode contains molybdenum as a main component.

The photoelectric-conversion semiconductor layer is preferably divided by at least one trench into a plurality of elements, and the plurality of elements are electrically connected in series.

A solar cell according to the present invention is characterized in comprising the photoelectric conversion device according to the present invention.

A process for producing a photoelectric conversion device according to the present invention is a process for producing a photoelectric conversion device wherein a lower electrode, a photoelectric-conversion semiconductor layer of a compound semiconductor material, and an upper electrode are formed in order on an anodized substrate in which an anodized oxide film as an electrically insulating film is formed on an aluminum base arranged at at least one surface of a metal substrate, and the lower electrode is formed on the anodized oxide film. The process is characterized in that before formation of the lower electrode, at least one insulative, antidiffusion layer suppressing diffusion, toward the anodized substrate, of at least one of alkali and/or alkaline earth metal elements contained in at least one alkali supply layer is formed on a side of the anodized oxide film on which the lower electrode is to be formed, and then at least one insulative, alkali supply layer containing the at least one of alkali and/or alkaline earth metal elements and supplying the at least one of alkali and/or alkaline earth metal elements to the photoelectric-conversion semiconductor layer during formation of the photoelectric-conversion semiconductor layer is formed over the at least one antidiffusion layer.

Registered Japanese Patent No. 4022577 (which is hereinafter referred to as JP4022577) discloses a process for producing a photoelectric conversion device in which doping with an alkali metal element is performed before or during formation of the photoelectric conversion layer, and an antidiffusion layer is arranged between a substrate and the photoelectric conversion layer for suppressing additional diffusion of the alkali metal element from the substrate to the photoelectric conversion layer during production of the device (claim 1). JP4022577 discloses as preferable examples of the antidiffusion layer an insulative antidiffusion layer of at least one of Al₂O₃, SiO₂, Si₃N₄, ZrO₂, and TiO₂ (in claim 8) and a conductive antidiffusion layer of at least one of TiN, Pt, and Pd (in claim 9).

The object of the provision of the antidiffusion layer in JP4022577 is to suppress additional diffusion of an alkali metal element from a glass substrate containing the alkali metal element in a photoelectric conversion device using the glass substrate. That is, the object of the provision of the antidiffusion layer disclosed in JP4022577 is not to suppress diffusion of an alkali metal element from an alkali supply layer to the substrate.

In addition, provision of an antidiffusion layer suppressing diffusion of an alkali metal element in the photoelectric conversion devices using an anodized substrate which are disclosed in JP2000-349320A and JP2009-267332A per se has not been conventionally reported.

Further, since the difference in the thermal expansion coefficient between the antidiffusion layer having the composition disclosed in claim 8 or 9 in JP4022577 and the Mo electrode (which is commonly used as a lower electrode) is great, stress distortion occurs in the photoelectric conversion device, and can cause microcracking, film peeling, and the like. However, it is known that when the lower electrode is not a Mo electrode, no ohmic contact is realized, so that the photoelectric conversion efficiency is lowered.

On the other hand, the photoelectric conversion device according to the present invention includes: one or more alkali supply layers which are formed between the anodized substrate and the lower electrode, and supply at least one of alkali and/or alkaline earth metal elements to the photoelectric-conversion semiconductor layer during formation of the photoelectric-conversion during formation of the photoelectric-conversion semiconductor layer; and one or more antidiffusion layers which are formed between the anodized substrate and the one or more alkali supply layers, and suppress diffusion, toward the anodized substrate, of the at least one of alkali and/or alkaline earth metal elements. That is, in the photoelectric conversion device according to the present invention, an anodized substrate is used, and the at least one of alkali and/or alkaline earth metal elements can be diffused to the photoelectric conversion layer during formation of the photoelectric conversion layer with high stability, efficiency, and reproducibility. Thus, the photoelectric conversion device according to the present invention is superior in the photoelectric conversion efficiency. In addition, in the photoelectric conversion device according to the present invention, the distortion of the device is reduced, and occurrence of microcracking, film peeling, and the like is suppressed.

### BRIEF DESCRIPTION OF THE DRAWINGS

FIG. 1A is a schematic cross-sectional view illustrating a cross section, along a lateral direction, of a photoelectric conversion device according to an embodiment of the present invention.

FIG. 1B is a schematic cross-sectional view illustrating a cross section, along a longitudinal direction, of the photoelectric conversion device according to the embodiment of the present invention.

FIGS. 2A and 2B are schematic cross-sectional views of the structures of anodized substrates.

FIG. 3 is a perspective view of a production method of the anodized substrate.

FIG. 4 is a schematic cross-sectional view of the structure of an anodized substrate using a two-layer clad base.

FIG. 5 is a diagram indicating the relationships between the lattice constant and the bandgap in representative Group compound semiconductors.

### DESCRIPTION OF PREFERRED EMBODIMENTS

### Photoelectric Conversion Device

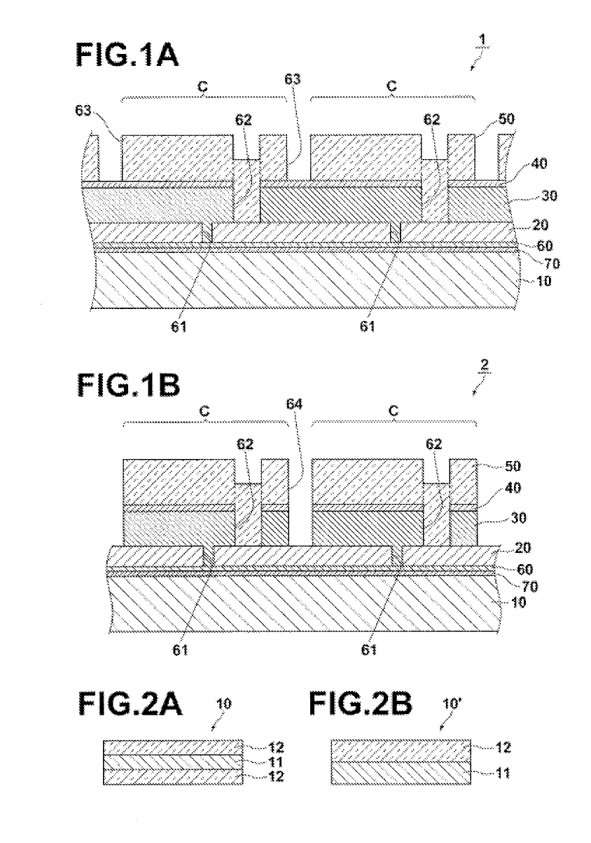

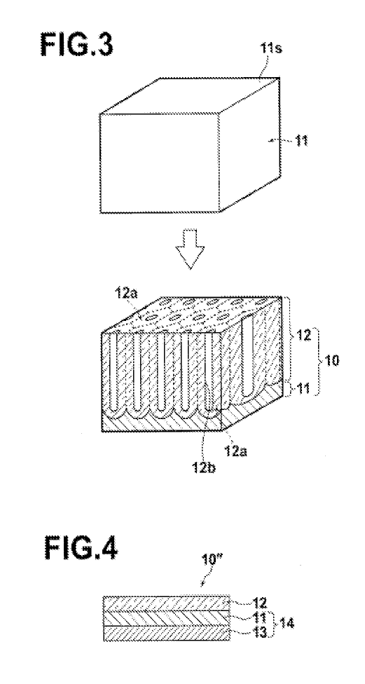

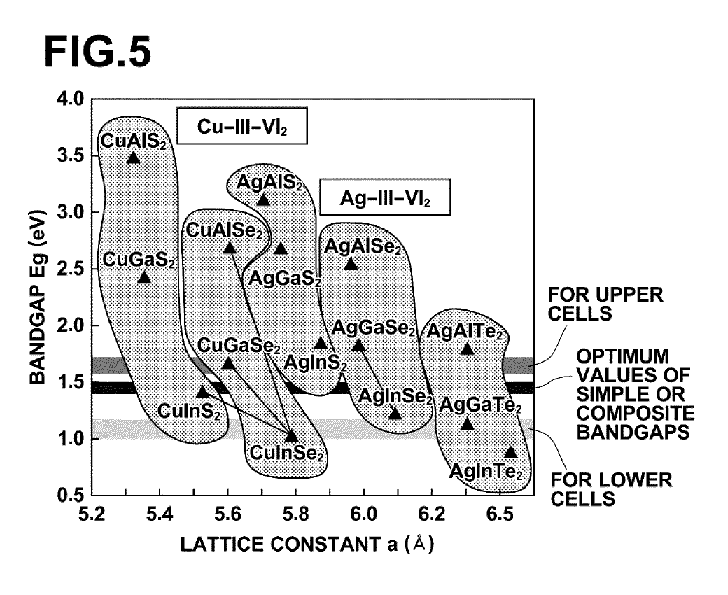

A structure of a photoelectric conversion device as an embodiment of the present invention is explained below with reference to the accompanying drawings. FIG. 1A is a schematic cross-sectional view illustrating a cross section, along a lateral direction, of a photoelectric conversion device according to the embodiment of the present invention, FIG. 1B is a schematic cross-sectional view illustrating a cross section, along a longitudinal direction, of the photoelectric conversion device, FIGS. 2A and 2B are schematic cross-sectional views of the structures of anodized substrates, and FIG. 3 is a perspective view of a production method of the anodized substrate. In the drawings, the dimensions of the illustrated elements are differentiated from the dimensions of the elements of the actual photoelectric conversion device for clarification.

The photoelectric conversion device 1 has a laminated structure as a basic structure. In the laminated structure, a lower electrode (underside electrode) 20, a photoelectric conversion semiconductor layer 30, a buffer layer 40, and an upper electrode 50 are formed in this order on an anodized substrate 10. (Hereinafter the photoelectric-conversion semiconductor layer 30 is referred to as the photoelectric conversion layer 30.)

In the photoelectric conversion device 1, an alkali (alkaline earth) metal supply layer 60 is formed immediately below the lower electrode 20 (between the anodized substrate 10 and the lower electrode 20). The alkali (alkaline earth) metal supply layer 60 is insulative, contains one or more of alkali and alkaline earth metal elements, and supplies the one or more of alkali and alkaline earth metal elements to the photoelectric conversion layer 30 during formation of the photoelectric conversion layer 30. Further, an antidiffusion layer 70 is formed between the anodized substrate 10 and the alkali (alkaline earth) metal supply layer 60. The antidiffusion layer 70 is insulative, and suppresses diffusion, toward the anodized substrate 10, of the one or more of alkali and alkaline earth metal elements contained in the alkali (alkaline earth) metal supply layer 60.

Furthermore, the photoelectric conversion device 1 includes first trenches 61 penetrating through only the lower electrode 20 in the lateral cross section, second trenches 62 penetrating through the photoelectric conversion layer 30 and the buffer layer 40 in the lateral cross section, third trenches 63 penetrating through only the upper electrode 50 in the lateral cross section, and fourth trenches 64 penetrating through the upper electrode 50, the buffer layer 40, and the photoelectric conversion layer 30 in the longitudinal cross section. Thus, a great number of cells C are separated by the first to fourth trenches 61 to 64 in the photoelectric conversion device according to the present embodiment. Moreover, the second trenches 62 are filled with portions of the upper electrode 50, so that the upper electrode 50 of each cell C on a certain side is series connected to the lower electrode 20 of the adjacent cell C.

### <Anodized Substrate>

The anodized substrate 10 is a substrate obtained by anodizing at least one side of a metal substrate 14. The metal substrate 14 is constituted by a metal base 11 (Al base 11). In the anodized substrate 10, an anodized oxide film 12 may be formed on each side of the Al base 11 as the anodized substrate 10 illustrated in FIG. 2A, or an anodized oxide film 12 may be formed on only one side of the Al base 11 as the anodized substrate 10′ illustrated in FIG. 2B. The main component of the anodized oxide film 12 is Al₂O₃.

The Al base 11 (constituting the metal substrate 14) may be made of one of the JIS (Japanese Industrial Standards) 1000 series pure-aluminum materials and alloys of aluminum and other metal elements (e.g., Al—Mn-based alloys, Al—Mg-based alloys, Al—Mn—Mg-based alloys, Al—Zr-based alloys, Al—Si-based alloys, Al—Mg—Si-based alloys, and the like). (See Aluminum Handbook (in Japanese), 4th edition, Japan Light Metal Association, pp. 1-5 and 219-221, 1990.) Further, various microelements (e.g., Fe, Si, Mn, Cu, Mg, Cr, Zn, Bi, Ni, Ti, and the like) may be solid-solved in pure aluminum constituting the Al base 11 (in the metal substrate 14).

The anodization can be performed, for example, by dipping the Al base 11 (as an anode) and a cathode (as a counter electrode) in an electrolytic solution prepared for anodization, and applying a voltage between the cathode and the Al base 11, where the cathode is made of carbon, aluminum, or the like. The electrolytic solution is not specifically limited, and is preferably an acidic electrolytic solution containing one or more of sulfuric acid, phosphoric acid, chromic acid, oxalic acid, malonic acid, sulfamic acid (amidosulfonic acid), benzenesulfonic acid, and the like. When necessary, washing, polishing for smoothing, and the like are performed on the Al base 11 before the anodization.

Although the condition of the anodization depends on the type of the electrolytic solution, no further specific condition is imposed on the anodization. The anodization can be appropriately performed, for example, under the condition that the concentration of the electrolyte is 1 to 80 weight percent, the temperature of the electrolytic solution is 5° C. to 85° C., the current density is 0.005 to 0.60 A/cm², the applied voltage is 1 to 200 V, and the electrolysis time is 3 to 500 minutes. It is preferable that the electrolyte be one or a mixture of sulfuric acid, phosphoric acid, oxalic acid, and malonic acid. In the case where such an electrolyte is used, it is preferable that the concentration of the electrolytic solution be 4 to 30 weight percent, the current density be 0.05 to 0.30 A/cm², and the applied voltage be 30 to 150 V.

As illustrated in FIG. 3, when the Al base 11 is anodized from the surface 11s, the anodization progresses from the surface 11s along the direction approximately perpendicular to the surface 11s, and the anodized oxide film 12 is produced. The main component of the anodized oxide film 12 is Al₂O₃. The anodized oxide film 12 produced by the anodization has a structure in which microcolumns 12a having approximately equilateral hexagonal shapes in a plan view are closely arranged. In addition, micropores 12b straightly extending from the surface 11s in the depth direction are formed approximately at the centers of the respective microcolumns 12a, and each of the microcolumns 12a has a round bottom end. Normally, a barrier layer (normally having a thickness of 0.01 to 0.4 micrometers) is formed of the bottom portions of the microcolumns 12a, in which the micropores 12b are not formed.

In the photoelectric conversion device 1, the insulative antidiffusion layer 70 is formed on the anodized oxide film 12. In the case where the anodized oxide film 12 has a porous structure as explained above, the antidiffusion layer 70 formed over the anodized oxide film 12 extends to the inside of the micropores 12b. This is advantageous because peeling of the antidiffusion layer 70 becomes unlikely to occur due to an anchor effect.

The diameters of the micropores 12b in the microcolumns 12a are not specifically limited. However, from the viewpoint of the smoothness of the surface of the anodized film. 12 and the insulation characteristics of the anodized film 12, the diameters of the micropores 12b are preferably 200 nanometers or smaller, and more preferably 100 nanometers or smaller. However, in order to sufficiently produce the anchor effect, it is preferable that the diameters of the micropores 12b in the microcolumns 12a be 10 nanometers or greater.

The density of the micropores 12b in the anodized film 12 is not specifically limited. However, from the viewpoint of the insulation characteristics of the anodized film 12, the density of the micropores 12b is preferably 100 to 10,000 per square micrometers, more preferably 100 to 5,000 per square micrometers, and particularly preferably 100 to 1,000 per square micrometers.

The porous anodized oxide films have lower Young's moduli than the nonporous anodized oxide films. Therefore, the porous anodized oxide films are superior in the flexural strength and the resistance to cracks, which can be produced by the difference in the thermal expansion at high temperature.

The micropore 12b in the anodized oxide film 12 may undergo a known sealing process when necessary. For example, when a neutral electrolytic solution such as boric acid, instead of the acidic electrolytic solution, is used in the electrolysis, a dense anodized oxide film (a nonporous homogeneous film of aluminum oxide), instead of the anodized oxide film in which porous microcolumns are arrayed, is formed. Alternatively, it is possible to increase the thickness of the barrier layer by a pore filling technique, in which electrolysis is performed again by use of a neutral electrolytic solution after a porous anodized oxide film is formed by use of an acidic electrolytic solution. The thickening of the barrier layer increases the insulation performance of the film.

The arithmetic average surface roughness Ra of the anodized film 12 is not specifically limited. However, from the viewpoint of uniform formation of the photoelectric conversion layer 30, it is more preferable that the surface of the anodized film 12 have higher smoothness. The arithmetic average surface roughness Ra is preferably 0.3 micrometers or smaller, and more preferably 0.1 micrometers or smaller.

The thickness of the anodized film 12 is not specifically limited as long as the anodized oxide film 12 has sufficient insulation performance and sufficient surface hardness to prevent damage to the anodized oxide film 12 from mechanical impact during handling of the anodized oxide film 12. However, in some cases where the anodized oxide film 12 is too thick, a problem concerning flexibility can occur. In consideration of this problem, the preferable thickness of the anodized oxide film 12 is 0.5 to 50 micrometers. The thickness of the anodized oxide film 12 can be controlled by the magnitudes of the current, the voltage, and the electrolysis time in constant-current or constant-voltage electrolysis.

In consideration of the mechanical strength of the anodized substrate 10 and reduction in the thickness and weight of the anodized substrate 10, the thickness of the metal base 11 before the anodization is, preferably 0.05 to 0.6 millimeters, and more preferably 0.1 to 0.3 millimeters. In consideration of the insulation performance and the mechanical strength of the substrate and the reduction in the thickness and weight of the substrate, the thickness of the anodized oxide film 12 is preferably 0.1 to 100 micrometers.

As mentioned before in “Description of the Related Art,” although the anodized substrate of aluminum is a metal substrate having an insulation layer (anodized oxide film) in which the adhesiveness of the insulation layer is satisfactory, cracking or peeling occurs during film formation because of the thermal stress caused by the difference in the thermal expansion coefficient between the Al base, the photoelectric conversion layer 30, and the other films in the case where heating to high temperature is required during the production process. In addition, the strong internal stress in the compound semiconductor caused by the difference in the thermal expansion coefficient from the base can lower the photoelectric conversion efficiency.

In the case of the photoelectric conversion layer 30 according to the present embodiment, e.g., in the case where the photoelectric conversion layer 30 is a CIS (or CIGS) layer, the pressure-resistant performance cannot be preserved because of cracking or peeling caused by the thermal stress due to the relatively great difference in the linear thermal expansion coefficient between aluminum and CIS (or CIGS) when film formation is attempted at approximately 600° C., although the pressure-resistant performance can be preserved when film formation is performed at approximately 500° C. Generally, it is more preferable that the difference in the linear thermal expansion coefficient between the substrate and a formed film be smaller.

In the present embodiment, the difference in the linear thermal expansion coefficient between the metal substrate 14 and the compound semiconductor layer at room temperature (23° C.) is preferably smaller than 7×10⁻⁶/K, and more preferably smaller than 3×10⁻⁶/K.

Therefore, in order to produce a substrate which withstands formation of a semiconductor film at higher temperature, it is preferable to use a metal substrate 14 in which the Al base 11 is integrally formed with a metal base 13 having high rigidity, high heat resistance, and a linear thermal expansion coefficient near the linear thermal expansion coefficient of the photoelectric conversion layer 30 within the preferable range (FIG. 4).

In the anodized substrate 10″ illustrated in FIG. 4, a metal substrate 14 (which may be hereinafter referred to as a clad member 14) in which an Al base 11 is arranged on a surface of a metal base 13 and is integrally formed with the metal base 13 is prepared, an anodized oxide film 12 of aluminum having a porous structure is formed as an insulation layer on a surface of the Al base 11 by anodizing the surface of the Al base 11. Therefore, the anodized substrate 10″ has a three-layer structure formed of the metal base 13, the Al base 11, and the anodized oxide film 12.

The material of the metal base 13 is not specifically limited as long as the material is a metal having high rigidity, high heat resistance, and a linear thermal expansion coefficient smaller than aluminum, and can be appropriately chosen by stress calculation on the basis of the structures and the material characteristics of the anodized substrate 10″ and the photoelectric conversion circuit formed above the anodized substrate 10″.

In the case where the photoelectric conversion layer 30 is formed of a CIS-based material, a CIGS-based material, or the like, the metal base 13 may be made of one of steels (including alloy steels) and the like. For example, it is preferable that the metal base 13 be made of one of the steel materials being disclosed in Japanese Unexamined Patent Publication No. 2009-132996 or the like and including carbon steels, ferritic stainless steels, and the like. At this time, it is also preferable that the metal base 13 have a greater thickness than the Al base 11.

Although details of the photoelectric conversion layer formed on the anodized substrate 10 are explained later, the linear thermal expansion coefficients of the main compound semiconductors are as follows. That is, the linear thermal expansion coefficient of GaAs as a representative of the Group III-V compound semiconductors is 5.8×10⁻⁶/K, the linear thermal expansion coefficient of CdTe as a representative of the Group II-VI compound semiconductors is 4.5×10⁻⁶/K, and the linear thermal expansion coefficient of Cu(InGa)Se₂ as a representative of the Group compound semiconductors is 10×10⁻⁶/K.

Although the thickness of the metal base 13 can be arbitrarily set in consideration of handleability (strength and flexibility) during a production process and during use of the photoelectric conversion devide or solar cell, it is preferable that the metal base 13 has a thickness of 10 micrometers to 1 millimeter.

The manner of the junction of the metal base 13 and the Al base 11 is arbitrary as long as the metal base 13 and the Al base 11 are integrally joined and adhesion can be secured. For example, the junction of the metal base 13 and the Al base 11 can be realized by vapor phase deposition (such as evaporation or sputtering) of aluminum on the metal base 13, hot dipping in molten aluminum, aluminum electroplating using a nonaqueous electrolytic solution, pressure joining or the like after surface cleaning.

The anodization of the clad member 14 can be performed by dipping the metal base 13 (as an anode) in an electrolytic solution together with a cathode, and applying a voltage between the anode and the cathode. At this time, the metal base 13 dipped in the electrolytic solution is required to be masked by an insulator, because when the metal base 13 comes in contact with the electrolytic solution a local battery is formed between the Al base 11 and the metal base 13. Specifically, in the case where the clad member 14 has a two-layer structure of the metal base 13 and the Al base 11, the surfaces, as well as the end faces, of the steel member 13 are required to be insulated. Details of the above anodization are similar to the aforementioned anodization.

As described above, the clad member 14 in which the Al base 11 is integrally formed with the metal base 13 on one side of the metal base 13 is used as a substrate, and an anodized substrate 10″ is produced by forming an anodized oxide film on a surface of the Al base 11 in the clad member 14, where the metal base 13 is made of a metal having high rigidity, high heat resistance, and a linear thermal expansion coefficient smaller than aluminum. Therefore, occurrence of cracks in the anodized oxide film. 12 can be suppressed even during a process of forming the photoelectric conversion layer 30 of a compound semiconductor on the substrate, although the temperature of the substrate is high (500° C. or higher) during the process. Thus, high insulation performance can be maintained even after the above process. The reason is considered that the thermal expansion of the Al base 11 is constrained by the metal base 13, the thermal expansion of the entire metal substrate 14 is controlled by the thermal expansion characteristics of the metal base 13, and the Al base 11 (having a small Young's modulus) existing between the metal base 13 and the anodized oxide film 12 reduces the stress imposed on the anodized oxide film 12 by the difference in the thermal expansion between the metal base 13 and the anodized oxide film 12.

### <Example of Design Change in Metal Substrate Having Insulation Layer>

Although the anodized substrate in which the metal base 13 has the cladding on only one side as illustrated in FIG. 4 are explained above, the clad member 14 is not limited to such a structure.

It is possible to produce a metal substrate with an insulation layer by using a metal substrate in which Al members are formed on both sides of the metal substrate. In this case, it is possible to perform anodization on only one of the Al members formed on only one side of the metal substrate and form an anodized oxide film on only the one of the Al members. When the metal substrate in which Al members are formed on both sides of the metal substrate is anodized, in order to prevent formation of a local battery of the metal base 13 and the Al base 11, insulation by masking is necessary. When the Al members on both sides are anodized, it is necessary to insulate the ends of the metal substrate by masking. When only one of the Al members on one side is anodized, it is necessary to insulate the surface opposite to the anodized surface of the metal substrate as well as the ends of the metal substrate.

Further, when the temperature is raised during the process of forming the compound semiconductor layer, thermal stress can cause curling of the metal substrate. Therefore, in the case where the Al members are formed on both sides of the steel member, it is preferable to form the anodized oxide film 12 on both the Al members.

### <Photoelectric Conversion Layer>

The photoelectric conversion layer 30 contains as one or more main components one or more compound semiconductors having a chalcopyrite structure and being composed of at least one Group Ib element, at least one Group IIIb element, and at least one Group VIb element. Such compound semiconductors are known to exhibit high optical absorptance and high photoelectric conversion efficiency. Preferably, the at least one Group Ib element in the one or more main components of the photoelectric conversion layer 30 is at least one of copper (Cu) and silver (Ag), the at least one Group IIIb element in the one or more main components of the photoelectric conversion layer 30 is at least one of aluminum (Al), gallium (Ga), and indium (In), and the at least one Group VIb element in the one or more main components of the photoelectric conversion layer 30 is at least one of sulfur (S), selenium (Se), and tellurium (Te). The following are examples of such a semiconductor compound.

The following are examples of the above semiconductor compounds.

CuAlS₂, CuGaS₂, CuInS₂, CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ) (S, Se)₂, Ag(In₁₋ₓGaₓ)Se₂, Ag(In₁₋ₓGaₓ) (S, Se)₂

Particularly preferably, the photoelectric conversion layer 30 contains CuInSe₂ (CIS) and/or Cu (In, Ga)Se₂ (CIGS), since CIS and CIGS are semiconductors having a chalcopyrite structure, and are reported to exhibit high optical absorptance and high energy conversion efficiency. In addition, since the degree of deterioration of CIS or CIGS caused by irradiation with light and the like is relatively small, CIS and CIGS have high durability.

Further, the photoelectric conversion layer 30 contains impurities for realizing a semiconductor of a desired conductive type. The photoelectric conversion layer 30 can be doped with such impurities by diffusion from an adjacent layer and/or by another active doping process.

The concentrations of the constituent elements of the Group I-III-VI semiconductor and/or the impurities in the photoelectric conversion layer 30 may have a distribution, and the photoelectric conversion layer 30 may contain a plurality of regions having different semiconductor characteristics such as n-type, p-type, and i-type. For example, in the case where the photoelectric conversion layer 30 is formed of a CIGS-based material, the bandgap, the carrier mobility, and the like can be controlled by varying the amount of gallium along the thickness direction so as to produce a distribution along the thickness direction, and therefore the photoelectric conversion layer 30 can be designed so as to realize high photoelectric conversion efficiency.

The photoelectric conversion layer 30 may contain one or more semiconductor materials other than the Group I-III-VI semiconductor. For example, the one or more semiconductor materials may be a semiconductor material which is composed of one or more Group IVb elements such as silicon (i.e., a Group IV semiconductor), a semiconductor material which is composed of one or more Group IIIb elements and one or more Group Vb elements such as GaAs (i.e., a Group III-V semiconductor), or a semiconductor material which is composed of one or more Group IIb elements and one or more Group VIb elements such as CdTe (i.e., a Group II-VI semiconductor).

As long as the characteristics of the photoelectric conversion layer 30 are not substantially affected, the photoelectric conversion layer 30 may contain an arbitrary component other than the one or more semiconductor materials and the impurities for realizing a desired conductive type of the semiconductor.

The CIGS layer can be formed by multisource simultaneous evaporation, selenization, sputtering, hybrid sputtering, mechanochemical processes, or other processes.

1) The three-stage process proposed by J. R. Tuttle et al., “The Performance of Cu(In,Ga)Se₂-Based Solar Cells in Conventional and Concentrator Applications”, Material Research Society (MRS) Symposium Proceedings, Vol. 426, pp. 143-151, 1996) and the coevaporation process proposed, for example, by L. Stolt et al., “THIN FILM. SOLAR CELL MODULES BASED ON CU (IN, GA)SE₂ PREPARED BY THE COEVAPORATION METHOD”, Proceedings of the 13th European Photovoltaic Solar Energy Conference, pp. 1451-1455, 1995) are known as the multisource simultaneous evaporation processes for formation of a CIGS layer.

In the three-stage process, initially, evaporation of In, Ga, and Se is simultaneously performed in a high vacuum at the substrate temperature of 300° C. Then, the substrate temperature is raised to 500° C. to 560° C., and evaporation of Cu and Se is simultaneously performed. Thereafter, evaporation of In, Ga, and Se is simultaneously performed again. On the other hand, in the coevaporation process proposed by the Stolt reference, Cu-rich CIGC is evaporated in the initial stage, and thereafter In-rich CIGS is evaporated.

Further, in order to improve the crystallinity of the CIGS film, the following techniques for improving the three-stage process and the coevaporation process have been proposed.

(a) A technique using ionized gallium, which has been proposed, for example, by H. Miyazaki et al., “Growth of high-quality CuGaSe₂ thin films using ionized Ga precursor”, Physica status solidi (a), Vol. 203, No. 11, pp. 2603-2608, 2006.

(b) A technique using cracked selenium, which has been proposed, for example, by M. Kawamura et al., “Growth of Cu(In₁₋ₓGaₓ)Se₂ thin films using cracked selenium”, Proceedings of the 68th Autumn Meeting of the Japan Society of Applied Physics (held at Hokkaido Institute of Technology in 2007), Lecture No. 7p-L-6.

(c) A technique using radical selenium, which has been proposed, for example, by S. Ishizuka et al., “Preparation of Cu(In₁₋ₓGaₓ)Se₂ thin films using a Se-radical beam source and solar cell performance”, Proceedings of the 54th Spring Meeting of the Japan Society of Applied Physics (held at Aoyama Gakuin University in 2007), Lecture No. 29p-ZW-10.

(d) A technique using a photo-excited deposition process, which has been proposed, for example, by Y. Ishii et al., “High Quality CIGS Thin Films and Devices by Photo-Excited Deposition Process”, in the Proceedings of the 54th Spring Meeting of the Japan Society of Applied Physics (held at Aoyama Gakuin University in 2007), Lecture No. 29p-ZW-14.

2) A process for formation of a CIGS layer by selenization is also called the two-stage process. In the two-stage process, first, a laminated film of metal precursors such as a lamination of a Cu layer and an In layer or a lamination of a (Cu—Ga) layer and an In layer is formed by sputtering, evaporation, electrodeposition, or the like. Then, the laminated film is heated to the temperature of approximately 450° C. to 550° C. in a selenium vapor or hydrogen selenide so as to produce a selenium compound such as Cu(In₁₋ₓGaₓ)Se₂ by thermal diffusion reaction. The selenization process using the selenium vapor, hydrogen selenide, or the like as above is called the vapor-phase selenization process. Alternatively, a solid-phase selenization process may be used. In the solid-phase selenization process, solid-phase selenium is deposited on metal precursor films, and the metal precursor films are selenized by solid-phase diffusion reaction in which the solid-phase selenium behaves as a selenium source.

In addition, in order to prevent rapid volume increase which can be caused by selenization, the following techniques are previously proposed. According to the first technique, a predetermined proportion of selenium is mixed in advance into the metal precursors as proposed, for example, by T. Nakada et al., “CuInSe₂-based solar cells by Se-vapor selenization from Se-containing precursors”, Solar Energy Materials and Solar Cells, Vol. 35, pp. 209-214, 1994. According to the second technique, a multilayer precursor film in which thin metal films are interleaved by selenium layers (e.g., a lamination of a Cu layer, an In layer, a Se layer, . . . , a Cu layer, an In layer, and a Se layer) is formed as proposed, for example, by T. Nakada et al., “THIN FILMS OF CuInSe₂ PRODUCED BY THERMAL ANNEALING OF MULTILAYERS WITH ULTRA-THIN STACKED ELEMENTAL LAYERS”, Proceedings of the 10th European Photovoltaic Solar Energy Conference (EU PVSEC), pp. 887-890, 1991.

Further, a process for forming a CIGS film having a graded bandgap has been proposed, for example, by K. Kushiya et al., “Fabrication of graded band-gap Cu(InGa)Se₂ thin-film mini-modules with a Zn (O, S, OH)ₓ buffer layer”, Solar Energy Materials and Solar Cells, Vol. 49, pp. 277-283, 1997. According to this process, first, a film of a Cu—Ga alloy is deposited, and then a film of In is deposited on the film of the Cu—Ga alloy. In addition, before selenization of the films, a graded concentration of Ga along the thickness direction is realized by natural thermal diffusion.

3) The following processes are known as the sputtering processes for formation of a CIS layer. According to the first process, a target of polycrystalline CuInSe₂ is used. The second process is a double-source sputtering process which has been proposed, for example, by J. H. Ermer et al., “CdS/CuInSe₂ JUNCTIONS FABRICATED BY DC MAGNETRON SPUTTERING OF Cu₂Se AND In₂Se₃”, Proceedings of the 18th IEEE Photovoltaic Specialists Conference, pp. 1655-1658, 1985. In the double-source sputtering process, a Cu₂Se target and an In₂Se₃ target are used, and a mixture of H₂Se and Ar is used as sputtering gas. The third process is a triple-source sputtering process which has been proposed, for example, by T. Nakada et al., “Polycrystalline CuInSe₂ Thin Films for Solar Cells by Three-Source Magnetron Sputtering”, Japanese Journal of Applied Physics, Vol. 32, Part 2, No. 8B, pp. L1169-L1172, 1993. In the triple-source sputtering process, a Cu target, an In target, and a target of Se or CuSe are used, and sputtering is performed in Ar gas.

4) A hybrid sputtering process for formation of a CIS layer, which has been proposed, for example, by T. Nakada et al., “Microstructural Characterization for Sputter-Deposited CuInSe₂ Films and Photovoltaic Devices”, Japanese Journal of Applied Physics, Vol. 34, Part 1, No. 9A, pp. 4715-4721, 1995, is different from the aforementioned triple-source sputtering process in that Cu and In are deposited by DC sputtering, and only Se is deposited by evaporation.

5) A mechanochemical process for formation of a CIGS layer has been proposed, for example, by T. Wada et al., “Fabrication of Cu(In, Ga)Se₂ thin films by a combination of mechanochemical and screen-printing/sintering processes”, Physica status solidi (a), Vol. 203, No. 11, pp. 2593-2597, 2006. In the mechanochemical process, raw materials corresponding to the composition of the CIGS layer are put into a planetary ball mill and mixed by mechanical energy so as to obtain a CIGS powder. Thereafter, the CIGS powder is applied to a surface of a substrate by screen printing, and then the applied CIGS powder is annealed so as to obtain a CIGS film.

6) In addition to the above processes, the CIGS layer can also be formed by screen printing, close-spaced sublimation, MOCVD, spraying, or the like. As disclosed, for example, in Japanese Unexamined Patent Publications Nos. 9 (1997)-074065 and 9 (1997)-074213, it is possible to obtain a crystal having a desired composition by forming a film of microparticles containing one or more Group Ib elements, one or more Group IIIb elements, and one or more Group VIb elements on a substrate by screen printing, spraying, or the like, and then thermally cracking the film. The process for thermally cracking the film may be performed in an atmosphere of one or more Group VIb elements.

FIG. 4 is a diagram indicating the relationships between the lattice constant and the bandgap in representative Group I-III-VI semiconductor compounds. It is possible to realize various bandgaps by controlling the composition of the Group I-III-VI semiconductor compound. When photons having energy greater than the bandgap of a semiconductor are injected into the semiconductor, the excess energy above the bandgap becomes thermal loss. Theoretical calculations based on the spectrum of the sunlight and various bandgaps teach that the photoelectric conversion efficiency is maximized when the bandgap is approximately 1.4 to 1.5 eV.

It is possible to realize the bandgap achieving high photoelectric conversion efficiency, for example, by increasing the bandgap, and the bandgap can be increased by increasing the Ga concentration in Cu(In, Ga)Se₂ (CIGS), increasing the Al concentration in Cu(In, Al)Se₂, or increasing the S concentration in Cu(In, Ga) (S, Se)₂. The bandgap of CIGS can be controlled in the range of 1.04 to 1.68 eV.

It is possible to realize a graded band structure by producing a variation of the composition along the thickness direction. The graded band structure includes a first type having a single graded bandgap and a second type having a double graded bandgap. The single graded bandgap increases along the direction from the light-entrance side to the opposite side. The double graded bandgap decreases along the direction from the light-entrance side toward the opposite side in the region from the light-entrance side to the pn junction, and increases along the same direction in the region beyond the pn junction. (See, for example, T. Dullweber et al., “A new approach to high-efficiency solar cells by band gap grading in Cu(In,Ga)Se₂ chalcopyrite semiconductors”, Solar Energy Materials and Solar Cells, Vol. 67, pp. 145-150, 2001.) In each of the first and second types, the gradation in the band structure produces an internal electric field, which accelerates the carriers generated by optical excitation, so that the carriers can easily reach the electrode, and the possibility of combination of the carriers with recombination centers is decreased. Thus, the efficiency in electric power generation is increased. (See, for example, the PCT Patent Publication No. WO2004/090995.)

In the case where a plurality of semiconductors having different bandgaps respectively suitable for different regions of the spectrum are used, it is possible to decrease the thermal loss caused by deviation of the photon energy from the bandgap, and therefore increase the efficiency in electric power generation. The solar cells in which a plurality of photoelectric conversion layers having different bandgaps as above are laminated are called the tandem solar cells. The efficiency in electric power generation in the two-layer tandem solar cells can be increased, for example, by using a combination of the photoelectric conversion layers respectively having the bandgaps of 1.1 eV and 1.7 eV.

### <Electrodes and Buffer Layer>

The lower electrode 20 and the upper electrode 50 are each formed of an electrically conductive material. In addition, the upper electrode 50, which is located on the light-entrance side, is required to be transparent.

Although the main component of the lower electrode 20 is not specifically limited, the lower electrode 20 contains as a main component preferably one or more of Mo, Cr, and W, and particularly preferably Mo. Although the thickness of the lower electrode 20 is not specifically limited, the thickness of the lower electrode 20 is preferably 0.2 to 0.6 micrometers, and more preferably 0.2 to 0.4 micrometers.

Although the main component of the upper electrode 50 is not specifically limited, the main component of the upper electrode 50 is preferably one or more of ZnO, ITO (indium tin oxide), and SnO₂. Although the thickness of the upper electrode 50 is not specifically limited, the thickness of the upper electrode 50 is preferably 0.6 to 1.0 micrometers.

The lower electrode 20 and the upper electrode 50 may have either a single-layer structure or a laminated structure (e.g., a two-layer structure).

Although the manners of forming the lower electrode 20 and the upper electrode 50 are not specifically limited, the lower electrode 20 and the upper electrode 50 may be formed by vapor phase deposition such as electron beam evaporation or sputtering.

Although the main component of the buffer layer 40 is not specifically limited, the main component of the buffer layer 40 is preferably one or more of CdS, ZnS, ZnO, ZnMgO, and ZnS(O, OH). Although the thickness of the buffer layer 40 is not specifically limited, the thickness of the buffer layer 40 is preferably 0.03 to 0.1 micrometers.

In a preferable example, the compositions of the lower electrode 20, the buffer layer 40, the photoelectric conversion layer 30, and the upper electrode 50 are respectively Mo, CdS, CIGS, and ZnO.

Although the conductive types of the photoelectric conversion layer 30, the buffer layer 40, and the upper electrode are not specifically limited, normally, the photoelectric conversion layer 30 is a p-type, the buffer layer 40 is an n-type (e.g., an n-type CdS), the upper electrode 50 is an n-type (e.g., an n-type ZnO) or a laminate of an i-type layer and an n-type layer (e.g., an i-type ZnO layer and an n-type ZnO layer). It is considered that in such a case, a pn junction or a pin junction is realized between the photoelectric conversion layer 30 and the upper electrode 50. In the structure in which the buffer layer 40 of CdS is formed on the photoelectric conversion layer 30, it is possible to consider that Cd diffuses into the photoelectric conversion layer 30, so that an n-type layer is formed in the near-surface region of the photoelectric conversion layer 30, and a pn junction is produced in the photoelectric conversion layer 30. Alternatively, it is possible to realize a pin junction in the photoelectric conversion layer 30 by further forming an i-type layer under the n-type layer in the photoelectric conversion layer 30.

### <Alkali Supply Layer>

The alkali supply layer 60 contains one or more of alkali and alkaline earth metal elements, and supplies (ions of) the one or more of alkali and alkaline earth metal elements (as one or more dopants) to the photoelectric conversion layer 30 during formation of the photoelectric conversion layer 30. In the present embodiment, the alkali supply layer 60 is formed of an electrically insulative material immediately below the lower electrode 20. The alkali supply layer 60 may have either a single-layer structure or a laminated structure of layers having different compositions.

The alkali metal elements which can constitute the alkali supply layer 60 include Li, Na, K, Rb, and Cs, and the alkaline earth metal elements which can constitute the alkali supply layer 60 include Be, Mg, Ca, Sr, and Ba. From the viewpoints of availability of a compound which is chemically stable and capable of being easily handled, a tendency to be emitted from the alkali supply layer 60 when being heated, and the effect of greatly improving the crystallinity of the photoelectric conversion layer 30, the alkali supply layer 60 contains preferably one or more of the alkali metal elements Na, K, Rb, and Cs, more preferably one or both of Na and K, and particularly preferably Na.

In the case where the main component of the alkali supply layer 60 is silicon oxide and the alkali supply layer 60 contains one or more sodium compounds, the content (concentration) of the one or more sodium compounds (for example, in the form of an oxide, Na₂O) in the alkali supply layer 60 is equivalent to 10% to 30% of Na₂O (i.e., 7 to 20 at. % of Na) either at the time the alkali supply layer 60 is formed, or at the time the photoelectric conversion layer 30 is formed. Preferably, the content of the one or more sodium compounds in the alkali supply layer 60 is equivalent to 15% to 25% of Na₂O (i.e., 10 to 16 at. % of Na).

The reason why the alkali supply layer 60 contains one or more sodium compounds is that sodium compounds which are chemically stable and capable of being easily handled can be easily obtained, the one or more sodium compounds can be easily emitted from the alkali supply layer 60 when the alkali supply layer 60 is heated, and the crystallinity of the photoelectric conversion layer 30 can be effectively improved by the one or more sodium compounds.

The composition of the alkali supply layer 60 is not specifically limited as long as the content in the alkali supply layer 60 is equivalent to 10% to 30% of Na₂O (i.e., 7 to 20 at. % of Na). For example, the alkali supply layer 60 may contain one or more alkali and alkaline earth metal elements.

The alkali supply layer 60 can be formed of an insulative material composed of a compound containing silicon oxide as a main component and one or more sodium compounds. The alkali supply layer 60 may have either a single-layer structure or a laminated structure of layers having different compositions.

If the Na₂O equivalent content in the alkali supply layer 60 is less than 10% (i.e., if the Na equivalent content in the alkali supply layer 60 is less than 7 at. %), the amount of alkali metal diffused into the photoelectric conversion layer 30 is too small, so that the photoelectric conversion efficiency becomes low. In addition, if the amount of alkali metal diffused into the photoelectric conversion layer 30 is small, it is necessary to thicken the alkali supply layer 60 in order to sufficiently supply alkali metal to the photoelectric conversion layer 30. However, if the alkali supply layer 60 is thickened, peeling can start from the alkali supply layer 60. Therefore, it is impossible to thicken the alkali supply layer 60.

On the other hand, if the Na₂O equivalent content of the one or more alkali and alkaline earth metals in the alkali supply layer 60 exceeds 30% (i.e., if the Na equivalent content in the alkali supply layer 60 exceeds 20 at. %), it is difficult to produce a target for use in formation of the alkali supply layer 60 by sputtering. For example, the component uniformity of the target is lost.

The alkali supply layer 60 in the present embodiment may be either an organic layer or an inorganic layer. For example, the inorganic layer may contain silicon oxide as a main component and one or more sodium compounds. In the case where the alkali supply layer 60 is formed of one or more silicate glass compounds containing one or more sodium compounds, the Na₂O equivalent content of the one or more sodium compounds in the silicate glass is 10% to 30%.

For example, the alkali supply layer 60 may be formed of a layer of silicate glass containing one or more sodium compounds. An example of such silicate glass is soda lime glass (SLG), which contains sodium oxide (Na₂O) as a sodium compound as indicated in Table 1. In this case, the content of the one or more sodium compounds in the alkali supply layer 60 is the content of Na₂O in the soda lime glass indicated in Table 1. The content of Na₂O in the soda lime glass of Table 1 is 15%. That is the Na₂O equivalent content in the soda lime glass of Table 1 is 15%, and the Na equivalent content in the soda lime glass of Table 1 is 10 at. %. The soda lime glass is also called green (or blue) glass or soda lime silica glass.

TABLE 1

| Component | Content (%) |
|---|---|
| SiO₂ | 72 |
| Na₂O | 15 |
| CaO | 7.2 |
| Ba₂O₃ | 4 |
| Al₂O₃ | 2 |
| Fe₂O₃ | 0.09 |
| TiO₂ | 0.002 |

In the soda lime glass of Table 1, increase or decrease in the content of the sodium compound corresponds to increase or decrease in the amount of the Na₂O, and is accompanied by increase or decrease in the amounts of the SiO₂ and the like. In addition, in the case where a layer of soda lime glass is formed as the alkali supply layer 60, the layer can be formed by, for example, PVD (physical vapor phase deposition) such as RF sputtering, evaporation, or the like in which soda lime glass is used as an evaporation source.

The thickness of the alkali supply layer 60 is preferably 50 to 200 nanometers since peeling is likely to occur in the case where the alkali supply layer 60 is thick.

According to the present embodiment, since the Na₂O equivalent content (concentration) of the one or more sodium compounds is 10% to 30% of Na₂O (i.e., the Na equivalent content (concentration) of the one or more sodium compounds is 7 to 20 at. %), the alkali supply layer 60 can supply alkali metal sufficient to improve the photoelectric conversion efficiency even in the case where the average thickness of the alkali supply layer 60 is as small as 50 to 200 nanometers. Therefore, the thickness of the alkali supply layer 60 can be reduced according to the present invention, so that it is possible to prevent the start of peeling from the alkali supply layer 60, reduce the time needed for formation of films including the alkali supply layer 60, and increase the productivity of the solar cell. In particular, increase in the content of the one or more sodium compounds facilitates the effects of increasing the photoelectric conversion efficiency of the photoelectric conversion layer 30, and reducing the time needed for formation of films including the alkali supply layer 60. Thus, it is preferable that the content of the one or more sodium compounds in the alkali supply layer 60 be close to the upper limit, which is the Na₂O equivalent content of 30% (i.e., the Na equivalent content of 20 at. %).

According to the present invention, it is possible to appropriately and satisfactorily control the amount of diffusion of sodium from the alkali supply layer 60 into the photoelectric conversion layer 30 by the thickness of the alkali supply layer 60.

The concentration of the alkali (and alkaline earth) metal elements is not specifically limited as long as the concentration is at such a level that a sufficient amount of alkali (and alkaline earth) metal can be supplied to the photoelectric conversion layer 30.

According to the present embodiment, the alkali supply layer 60 is arranged immediately below the lower electrode 20. Although a structure in which the alkali supply layer 60 is arranged between the lower electrode 20 and the photoelectric conversion layer 30 appears to be preferable from the viewpoints of the supply of alkali to the photoelectric conversion layer 30 and suppression of diffusion of alkali toward the substrate 10, in some cases, the photoelectric conversion efficiency can be increased by existence of an intermediate layer which is formed in the photoelectric conversion layer 30 (of one or more compound semiconductors) by reaction of the components of the photoelectric conversion layer 30 with the components of the lower electrode 20. For example, it is known that in the case where the lower electrode 20 is formed of molybdenum, and the photoelectric conversion layer 30 is a CIS-based (or CIGS-based) semiconductor layer, a Mo—Se layer as the intermediate layer plays a role of maintaining an electrically desirable junction condition. Therefore, if the alkali supply layer 60 is arranged between the lower electrode 20 and the photoelectric conversion layer 30, formation of the above intermediate layer can be impeded, so that the photoelectric conversion efficiency can be lowered.

As explained above, according to the present embodiment, the effect of increasing the photoelectric conversion efficiency by use of the alkali supply layer 60 can be maximized since the alkali supply layer 60 is arranged immediately below the lower electrode 20.

### <Antidiffusion Layer>

The antidiffusion layer 70 is provided for suppressing diffusion, toward the anodized substrate 10, of the one or more of alkali (and alkaline earth) metal elements contained in the alkali supply layer 60. In the present embodiment, the antidiffusion layer 70 is formed of an electrically insulating material between the anodized substrate 10 and the alkali supply layer 60.

The composition of the antidiffusion layer 70 is not specifically limited as long as the composition realizes the function of suppressing diffusion of the one or more of alkali (and alkaline earth) metal elements. However, the antidiffusion layer 70 is preferably formed of a material having a thermal expansion coefficient close to the thermal expansion coefficient of the anodized substrate 10. Specifically, it is preferable that the thermal expansion coefficient of the antidiffusion layer 70 be approximately identical to aluminum oxide at 300K. The linear expansion coefficient of aluminum oxide is 5.4×10⁻⁶/K. It is preferable that the antidiffusion layer 70 be formed of a material having a linear expansion coefficient of 5.4×10⁻⁶/K±2.5×10⁻⁶/K (i.e., in the range from 3.9×10⁻⁶/K to 7.9×10⁻⁶/K).

For example, the main component of the antidiffusion layer 70 may be SiO₂ (having the linear expansion coefficient of 7.4×10⁻⁶/K), TiO₂ (having the linear expansion coefficient of 7.5×10⁻⁶/K), Al₂O₃ (having the linear expansion coefficient of 5.4×10⁻⁶/K), ZrO₂ (having the linear expansion coefficient of 8.8×10⁻⁶/K), CeO₂ (having the linear expansion coefficient of 9.5×10⁻⁶/K), and HfO₂ (having the linear expansion coefficient of 6.5×10⁻⁶/K). It is particularly preferable that the main component of the antidiffusion layer 70 be one or both of SiO₂ and TiO₂. The antidiffusion layer 70 may have a laminated structure of one or more SiO₂ layers and one or more TiO₂ layers.

### <Advantages of the Present Invention>

The above values of the linear expansion coefficients are indicated in “Butsuri Data Jiten (Physical Data Book, in Japanese),” The Physical Society of Japan (ed.), Asakura Publishing, pp. 161-163, 2006.

The manner of formation of the antidiffusion layer 70 is not specifically limited. For example, the antidiffusion layer 70 may be formed by evaporation or the like.

The thickness of the antidiffusion layer 70 is not specifically limited as long as the thickness is at such a level that the antidiffusion layer 70 can satisfactorily suppress diffusion of the one or more of alkali and alkaline earth metal elements toward the anodized substrate 10. The average thickness of the antidiffusion layer 70 may be 10 to 200 nanometers, and is preferably approximately 10 to 100 nanometers.

### <Other Layers>

It is possible to arrange one or more arbitrary layers other than the layers explained above, when necessary. For example, it is possible to arrange an adhesion layer (buffer layer) between the anodized substrate 10 and the lower electrode 20, and/or between the lower electrode 20 and the photoelectric conversion layer 30 for enhancing the adhesiveness between the layers when necessary.

The photoelectric conversion device 1 according to the present embodiment is formed as follows.

Since the photoelectric conversion device 1 according to the present embodiment uses the anodized substrate 10, the photoelectric conversion device 1 is lightweight and flexible, and can be manufactured at low cost.

The photoelectric conversion device 1 comprises the alkali supply layer 60 and the antidiffusion layer 70. The alkali supply layer 60 is electrically insulative and formed immediately below the lower electrode 20, contains the one or more of alkali (and alkaline earth) metal elements, and supplies the one or more of alkali (and alkaline earth) metal elements to the photoelectric conversion layer 30 during formation of the photoelectric conversion layer 30. The antidiffusion layer 70 is formed between the anodized substrate 10 and the alkali supply layer 60, and suppresses diffusion, toward the anodized substrate 10, of the one or more of alkali (and alkaline earth) metal elements contained in the alkali supply layer 60.

Since the alkali supply layer 60 is formed immediately below the lower electrode 20, the one or more of alkali (and alkaline earth) metal elements can be efficiently supplied to and diffused in the photoelectric conversion layer 30. In addition, since the antidiffusion layer 70 is formed immediately below the alkali supply layer 60, diffusion, toward the anodized substrate 10, of the one or more of alkali (and alkaline earth) metal elements contained in the alkali supply layer 60 can be suppressed during the process preceding the formation of the photoelectric conversion layer 30.

Therefore, according to the present embodiment, the one or more of alkali (and alkaline earth) metal elements can be supplied to and diffused in the photoelectric conversion layer 30 with satisfactory stability, efficiency, and reproducibility during formation of the photoelectric conversion layer 30 so as to achieve a desired concentration of the one or more of alkali (and alkaline earth) metal elements in the photoelectric conversion layer 30. In addition, according to the present embodiment, the one or more of alkali (and alkaline earth) metal elements can be supplied to the photoelectric conversion layer 30 during the formation of the photoelectric conversion layer 30 so that the concentration of the one or more of alkali (and alkaline earth) metal elements becomes approximately uniform over the entire area of the photoelectric conversion layer 30.

Since, according to the present embodiment, the one or more of alkali (and alkaline earth) metal elements can be stably supplied to the photoelectric conversion layer 30 so as to achieve the desired concentration, the crystallinity of the photoelectric conversion layer 30 is satisfactory, and the photoelectric conversion device according to the present embodiment is superior in the photoelectric conversion efficiency.

Since diffusion of the one or more of alkali (and alkaline earth) metal elements toward the anodized substrate 10 can be suppressed during the process preceding the formation of the photoelectric conversion layer 30, deterioration of the anodized oxide film 12 caused by the diffusion of the one or more of alkali (and alkaline earth) metal elements can be suppressed. Therefore, it is possible to suppress distortion of the photoelectric conversion device, and film peeling, microcracking, and the like of the photoelectric conversion layer 30, which can be caused by the deterioration of the anodized oxide film 12.

As mentioned before, the main component of the antidiffusion layer 70 is preferably SiO₂ and/or TiO₂. In this case, the difference in the thermal expansion coefficient between the anodized substrate 10 and the antidiffusion layer 70 is small. Therefore, it is possible to suppress distortion of the photoelectric conversion device, and film peeling, microcracking, and the like of the photoelectric conversion layer 30, which can be caused by the difference in the thermal expansion coefficient.

According to the present embodiment, each of the alkali supply layer 60 and the antidiffusion layer 70 is formed of an electrically insulating material, and the alkali supply layer 60 and the antidiffusion layer 70 are arranged between the anodized substrate 10 and the lower electrode 20. Such an arrangement is effective in increasing the insulation performance between the anodized substrate 10 and the lower electrode 20.

The photoelectric conversion device according to the present embodiment can be preferably used in solar cells or the like. Solar cells can be produced by attaching a cover glass, a protection film, and the like to the photoelectric conversion device as appropriate.

### <Design Change>

The present invention is not limited to the embodiment explained above, and the structures of the embodiment may be further modified within the scope of the present invention as needed.

Concrete examples of the present invention are explained below.

### Concrete Example 1

An antidiffusion layer of titanium oxide (TiO₂) having a thickness of 200 nanometers has been formed on a substrate of commercially available soda lime glass (SLG) by sputtering. In addition, a lower electrode of metal molybdenum having a thickness of 800 nanometers has been formed on the antidiffusion layer by DC sputtering, and a semiconductor layer of Cu(In_{0.7}Ga_{0.3})Se₂ having a thickness of 2 micrometers has been formed on the Mo lower electrode at the substrate temperature of 550° C. by evaporation using a K cell (Knudsen-Cell) as an evaporation source.

Thereafter, a buffer layer of CdS having a thickness of 50 nanometers has been formed on the surface of the CIGS layer by CBD (chemical bath deposition). Subsequently, a layer of ZnO having a thickness of 50 nanometers has been formed on the surface of the CdS buffer layer by sputtering. Further, a transparent electrode layer of Al—ZnO having a thickness of 300 nanometers has been formed by sputtering. Finally, a layer of aluminum as an output electrode has been formed on the surface of the Al—ZnO layer by evaporation.

### Concrete Example 2

A photoelectric conversion device as the concrete example 2 has been produced in a similar manner to the concrete example 1 except that the antidiffusion layer has been formed of SiO₂.

### Concrete Example 3

A photoelectric conversion device as the concrete example 3 has been produced in a similar manner to the concrete example 1 except that the antidiffusion layer has been formed of Al₂O₃.

### Comparison Example 1

A photoelectric conversion device as the comparison example 1 has been produced in a similar manner to the concrete example 1 except that the antidiffusion layer has not been formed.

### <Evaluation 1>

Measurement of the photoelectric conversion devices as the concrete examples 1 to 3 and the comparison example 1 has been performed by use of SIMS (secondary ion mass spectrometry). In the measurement, the primary ion type has been O2+ ion, and the acceleration voltage has been 6.0 kV. Although the Na concentration in CIGS has a distribution along the thickness direction, an average value has been obtained for evaluation by integration. Table 2 indicates the results of the evaluation. As indicated in Table 2, it has been confirmed that the antidiffusion layer of an oxide in the photoelectric conversion device as in each of the concrete examples 1 to 3 effectively reduces alkali diffusion.

TABLE 2

| | | Na Concentration of |
|---|---|---|
| | | CIGS Layer |
| | Antidiffusion Layer | (atoms/cm²) |
| Concrete Example 1 | TiO₂ | Below Detection Limit |
| Concrete Example 2 | SiO₂ | Below Detection Limit |
| Concrete Example 3 | Al₂O₃ | Below Detection Limit |
| Comparison Example 1 | None | 1 × 10¹⁸ |

### Concrete Examples 4 and Comparison Example 2

The concrete examples 4 have been produced as follows.

Three-layer laminate substrates (clad members) each formed of a ferritic stainless steel SUS430 having a thickness 50 micrometers and layers of high-purity aluminum (with the purity 4N) each having a thickness of 30 micrometers have been prepared. The surfaces of the clad members at which the stainless steel is exposed are covered by a masking film, and the clad members have undergone ultrasonic cleaning with ethanol and electrolytic polishing with a solution of ascetic acid and perchloric acid. Thereafter, the metal substrates having the cladding have been anodized with the acid aqueous solutions, the temperatures, and the electrolytic voltages which are indicated Table 3, where the electrolysis time is set so that the thickness of 9 micrometers is realized. Thus, anodized oxide films having the average diameters of the micropores and the average thicknesses as indicated in Table 3 have been produced. The geometry of the surface of the anodized oxide films have been observed by SEM (scanning electron microscope). Through the above steps, metal substrates with an insulation layer, which have a structure of an anodized oxide film, an Al layer, the stainless steel, an Al layer, and an anodized oxide film, have been obtained.

Next, an antidiffusion layer of titanium oxide (TiO₂) has been formed on each of the above metal substrates (with an insulation layer) by sputtering, an alkali supply layer of soda lime glass having the thickness indicated in Table 3 is formed on the antidiffusion layer, and a lower electrode of molybdenum having a thickness of 800 nanometers has been formed on the alkali supply layer by DC sputtering.

In addition, the comparison example 2 has been formed by preparing a commercially available substrate of alumina, and a layer of soda lime glass and an electrode of molybdenum has been formed in a similar manner to the concrete examples 4.

### <Evaluation 2>

The adhesiveness of the laminates of the concrete examples 4 and the comparison example 2 has been evaluated by performing a tape tear-off test on twenty samples of each of the concrete examples 4 and the comparison example 2. Specifically, the evaluation has been performed by applying a commercially available adhesive cellophane tape to the molybdenum film, tearing off the adhesive cellophane tape by pulling an end of the adhesive cellophane tape in a vertical direction by hand, and visually checking whether or not peeling of the molybdenum film occurs in the area on which the adhesive cellophane tape is applied. The results of the tape tear-off test are indicated in Table 3.

In Table 3, a blank circle is indicated for each example when no peeling has been observed in the twenty samples of the example and the function and the power generation efficiency of a photoelectric conversion devices produced by use of the example have been confirmed; a blank triangle is indicated for each example when peeling has been observed in one to nine of the twenty samples of the example and the function and the power generation efficiency of a photoelectric conversion devices produced by use of the example have been confirmed; and a cross is indicated for each example when peeling has been observed in more than nine of the twenty samples of the example or the photoelectric conversion efficiency of a photoelectric conversion devices produced by use of the example has not been able to be measured.

As indicated in Table 3, the effect of the soda lime glass (SLG) layer (as the alkali supply layer) and the antidiffusion layer on the power generation efficiency has been confirmed, and the effective thicknesses of the soda lime glass layer and the antidiffusion layer and other information have been obtained.

In addition, a tendency to occurrence of peeling has been observed in the comparison example 2 which uses the commercially available alumina substrate. The reason for the tendency is considered that the adhesiveness of a film formed on the commercially available alumina substrate, which does not have micropores, is lower than the adhesiveness of a film formed on the anodized oxide film having micropores.

TABLE 3

| | | | Electrolytic | Pore | | Thickness | Antidiffusion | | |
|---|---|---|---|---|---|---|---|---|---|
| | Acid Aqueous | Temperature | Voltage | Diameter | Thickness | of SLG | Layer | Tear-off | Power Generation |
| | Solution | (° C.) | (V) | (nm) | (μm) | (μm) | (μm) | Test | Efficiency (%) |
| Concrete | 0.5M Oxalic | 16 | 40 | 30 | 9 | 0 | None | ◯ | 10 |
| Examples 4 | Acid | | | | | | | | |
| | 0.5M Oxalic | 16 | 40 | 30 | 9 | 0 | 50 | ◯ | 10 |
| | Acid | | | | | | | | |
| | 0.5M Oxalic | 16 | 40 | 30 | 9 | 0 | 100 | ◯ | 10 |
| | Acid | | | | | | | | |
| | 0.5M Oxalic | 16 | 40 | 30 | 9 | 0 | 200 | ◯ | 10 |
| | Acid | | | | | | | | |
| | 1M | 35 | 15 | 11 | 9 | 0 | 100 | ◯ | 10 |
| | Sulfuric Acid | | | | | | | | |
| | 1M | 80 | 80 | 60 | 9 | 0 | 100 | ◯ | 10 |
| | Malonic Acid | | | | | | | | |
| | 0.5M Oxalic | 16 | 40 | 30 | 9 | 50 | None | Δ | 11 |
| | Acid | | | | | | | | |
| | 0.5M Oxalic | 16 | 40 | 30 | 9 | 50 | 50 | ◯ | 11 |
| | Acid | | | | | | | | |
| | 0.5M Oxalic | 16 | 40 | 30 | 9 | 50 | 100 | ◯ | 15 |
| | Acid | | | | | | | | |
| | 0.5M Oxalic | 16 | 40 | 30 | 9 | 50 | 200 | ◯ | 15 |
| | Acid | | | | | | | | |
| | 1M | 35 | 15 | 11 | 9 | 50 | 100 | ◯ | 15 |
| | Sulfuric Acid | | | | | | | | |
| | 1M | 80 | 80 | 60 | 9 | 50 | 100 | ◯ | 15 |
| | Malonic Acid | | | | | | | | |
| | 0.5M Oxalic | 16 | 40 | 30 | 9 | 100 | None | Δ | 12 |
| | Acid | | | | | | | | |
| | 0.5M Oxalic | 16 | 40 | 30 | 9 | 100 | 50 | Δ | 13 |
| | Acid | | | | | | | | |
| | 0.5M Oxalic | 16 | 40 | 30 | 9 | 100 | 100 | ◯ | 16 |
| | Acid | | | | | | | | |
| | 0.5M Oxalic | 16 | 40 | 30 | 9 | 100 | 200 | ◯ | 16 |
| | Acid | | | | | | | | |
| | 1M | 35 | 15 | 11 | 9 | 100 | 100 | ◯ | 16 |
| | Sulfuric Acid | | | | | | | | |
| | 1M | 80 | 80 | 60 | 9 | 100 | 100 | ◯ | 16 |
| | Malonic Acid | | | | | | | | |
| | 0.5M Oxalic | 16 | 40 | 30 | 9 | 150 | None | Δ | 13 |
| | Acid | | | | | | | | |
| | 0.5M Oxalic | 16 | 40 | 30 | 9 | 150 | 50 | Δ | 14 |
| | Acid | | | | | | | | |
| | 0.5M Oxalic | 16 | 40 | 30 | 9 | 150 | 100 | ◯ | 15 |
| | Acid | | | | | | | | |
| | 0.5M Oxalic | 16 | 40 | 30 | 9 | 150 | 200 | ◯ | 15 |
| | Acid | | | | | | | | |
| | 1M | 35 | 15 | 11 | 9 | 150 | 100 | Δ | 15 |
| | Sulfuric Acid | | | | | | | | |
| | 1M | 80 | 80 | 60 | 9 | 150 | 100 | ◯ | 15 |
| | Malonic Acid | | | | | | | | |
| | 0.5M Oxalic | 16 | 40 | 30 | 9 | 200 | None | Δ | 15 |
| | Acid | | | | | | | | |
| | 0.5M Oxalic | 16 | 40 | 30 | 9 | 200 | 50 | Δ | 15 |
| | Acid | | | | | | | | |
| | 0.5M Oxalic | 16 | 40 | 30 | 9 | 200 | 100 | Δ | 15 |
| | Acid | | | | | | | | |
| | 0.5M Oxalic | 16 | 40 | 30 | 9 | 200 | 200 | Δ | 15 |
| | Acid | | | | | | | | |
| | 1M | 35 | 15 | 11 | 9 | 200 | 100 | Δ | 15 |
| | Sulfuric Acid | | | | | | | | |
| | 1M | 80 | 80 | 60 | 9 | 200 | 100 | ◯ | 15 |
| | Malonic Acid | | | | | | | | |
| | 0.5M Oxalic | 16 | 40 | 30 | 9 | 1000 | None | X | — |
| | Acid | | | | | | | | |
| | 0.5M Oxalic | 16 | 40 | 30 | 9 | 1000 | 50 | X | — |
| | Acid | | | | | | | | |
| | 0.5M Oxalic | 16 | 40 | 30 | 9 | 1000 | 100 | X | — |
| | Acid | | | | | | | | |
| | 0.5M Oxalic | 16 | 40 | 30 | 9 | 1000 | 200 | X | — |
| | Acid | | | | | | | | |
| | 1M | 35 | 15 | 11 | 9 | 1000 | 100 | X | — |
| | Sulfuric Acid | | | | | | | | |
| | 1M | 80 | 80 | 60 | 9 | 1000 | 100 | X | — |
| | Malonic Acid | | | | | | | | |
| Comparison | — | — | — | — | — | 0 | — | ◯ | 10 |
| Example 2 | — | — | — | — | — | 50 | — | Δ | 12 |
| | — | — | — | — | — | 100 | — | Δ | 13 |
| | — | — | — | — | — | 150 | — | X | — |
| | — | — | — | — | — | 200 | — | X | — |
| | — | — | — | — | — | 300 | — | X | — |

### Concrete Examples 5

The samples of the concrete examples 4 produced by using the clad members and samples produced in similar manners to the concrete examples 4 except for use of Al substrates have been prepared and heated at 550° C. in a vacuum furnace for an hour. Then, the surface conditions of the above samples have been evaluated. Specifically, the evaluation has been performed by observing the surface of the photoelectric conversion layer by an optical microscope. In addition, an electrode of gold having a thickness of 0.2 micrometers and a diameter of 3.5 millimeters has been formed on the photoelectric conversion layer by masked evaporation, the resistance value between the upper electrode and the lower electrode has been measured for checking whether or not leakage due to microcracks or very small cracks which cannot be observed by the optical microscope occurs. The results of the evaluation are indicated in Table 4. In Table 4, a cross is indicated when partial peeling or a crack has been observed by the optical microscope, and a blank circle is indicated when no microcrack or very small crack has been determined to exist.

Thus, in the case where the substrate matching the photoelectric conversion layer with respect to the thermal expansion coefficient is used, it is possible to obtain a film having satisfactory quality and producing no crack even when the film is exposed to the temperature as high as 550° C.

TABLE 4

| Substrate | Crack Test (550° C.) |
|---|---|
| Al Substrate | X |
| Clad Member | ◯ |

1. A photoelectric conversion device wherein a lower electrode, a photoelectric-conversion semiconductor layer of a compound semiconductor material, and an upper electrode are formed in order on an anodized substrate in which an anodized oxide film as an electrically insulating film is formed on an aluminum base arranged at at least one surface of a metal substrate, and the lower electrode is formed on the anodized oxide film; wherein
said photoelectric-conversion semiconductor layer contains as a main component at least one compound semiconductor material having a chalcopyrite structure and being composed of at least one Group Ib element, at least one Group IIIb element, and at least one Group VIb element; and
said photoelectric conversion device includes,
at least one alkali supply layer which is insulative and formed between said anodized substrate and said lower electrode, contains at least one of alkali and alkaline earth metal elements, and supplies the at least one of alkali and alkaline earth metal elements to said photoelectric-conversion semiconductor layer during formation of the photoelectric-conversion semiconductor layer, and
at least one antidiffusion layer which is electrically insulative and formed between said anodized substrate and said at least one alkali supply layer, and suppresses diffusion, toward the anodized substrate, of said at least one of alkali and alkaline earth metal elements contained in the at least one alkali supply layer.

2. A photoelectric conversion device according to claim 1, wherein said at least one Group Ib element is at least one of copper and silver, said at least one Group IIIb element is at least one of aluminum, gallium, and indium, and said at least one Group VIb element is at least one of sulfur, selenium, and tellurium.

3. A photoelectric conversion device according to claim 1, wherein said lower electrode contains molybdenum as a main component.

4. A photoelectric conversion device according to claim 1, wherein said at least one antidiffusion layer is formed of one or more oxides having a linear thermal expansion coefficient which is approximately identical to a linear thermal expansion coefficient of aluminum oxide at 300K.

5. A photoelectric conversion device according to claim 4, wherein said at least one antidiffusion layer contains at least one of SiO₂ and TiO₂ as one or more main components.

6. A photoelectric conversion device according to claim 1, wherein said at least one antidiffusion layer has an average thickness of 10 to 200 nanometers.

7. A photoelectric conversion device according to claim 6, wherein said at least one antidiffusion layer has an average thickness of 10 to 100 nanometers.

8. A photoelectric conversion device according to claim 1, wherein said at least one alkali supply layer contains sodium.

9. A photoelectric conversion device according to claim 8, wherein said at least one alkali supply layer is formed of silicate glass containing a sodium compound.

10. A photoelectric conversion device according to claim 1, wherein said at least one alkali supply layer is formed by sputtering.

11. A photoelectric conversion device according to claim 1, wherein said at least one alkali supply layer has an average thickness of 50 to 200 nanometers.

12. A photoelectric conversion device according to claim 1, wherein in said metal substrate, said aluminum base is arranged on at least one surface of a metal base and is integrally formed with the metal base, and the metal base has a linear thermal expansion coefficient smaller than a linear thermal expansion coefficient of aluminum.

13. A photoelectric conversion device according to claim 1, wherein said anodized oxide film has a porous structure.

14. A photoelectric conversion device according to claim 1, wherein said metal substrate is a laminated substrate in which said aluminum base is arranged on at least one surface of a base and is integrally formed with the base, the base is made of a carbon steel or a ferritic stainless steel, said lower electrode contains molybdenum as a main component.

15. A photoelectric conversion device according to claim 1, wherein said photoelectric-conversion semiconductor layer is divided by at least one trench into a plurality of elements, and the plurality of elements are electrically connected in series.

16. A solar cell comprising said photoelectric conversion device according to claim 1.

17. A process for producing a photoelectric conversion device wherein a lower electrode, a photoelectric-conversion semiconductor layer of a compound semiconductor material, and an upper electrode are formed in order on an anodized substrate in which an anodized oxide film as an electrically insulating film is formed on an aluminum base arranged at at least one surface of a metal substrate, and the lower electrode is formed on the anodized oxide film; wherein
said method includes, before formation of said lower electrode,
forming, on a side of said anodized oxide film on which the lower electrode is to be formed, at least one antidiffusion layer which is insulative, and suppresses diffusion, toward the anodized substrate, of at least one of alkali and alkaline earth metal elements contained in at least one alkali supply layer, and
forming, over said at least one antidiffusion layer, said at least one alkali supply layer which is insulative, contains said at least one of alkali and alkaline earth metal elements, and supplies the at least one of alkali and alkaline earth metal elements to said photoelectric-conversion semiconductor layer during formation of the photoelectric-conversion semiconductor layer.
